(19) United States
(12) Patent Application Publication
(10) Pub. No.: US 2019/0158970 A1
(43) Pub. Date: May 23, 2019

(54) SOUND REPRODUCTION DEVICE

(71) Applicant: Panasonic Intellectual Property Management Co., Ltd., Osaka (JP)

(72) Inventors: FUMIYASU KONNO, Osaka (JP); SINNOSUKE NAGASAWA, Osaka (JP); ICHIRO OHNO, Osaka (JP)

(21) Appl. No.: 16/061,609

(22) PCT Filed: Dec. 20, 2016
(86) PCT No.: PCT/JP2016/005192

§ 371 Date: Jun. 12, 2018

(30) Foreign Application Priority Data
Dec. 25, 2015 (JP) 2015-255428

(51) Int. Cl. H04R 29/00; H03F 3/181; H03G 3/30

(52) U.S. Cl. CPC H04R 29/001; H03F 3/181; H03G 2201/103; H04R 2499/13; H03F 2200/03; H03G 3/3005

(57) ABSTRACT

Provided is a sound reproduction device that can accurately adjust a warning sound output from a loudspeaker. The sound reproduction device includes a loudspeaker unit including a loudspeaker and an identifier that identifies a characteristic of the loudspeaker and an amplifier unit that amplifies a signal corresponding to a sound output from the loudspeaker. The amplifier unit includes an amplifier that amplifies the signal input from a sound source and outputs the amplified signal to the loudspeaker, a determination unit, and an amplification degree adjuster. When the loudspeaker unit and the amplifier unit are connected to each other, the determination unit determines the characteristic of the loudspeaker from the identifier of the connected loudspeaker unit. The amplification degree adjuster adjusts the amplification degree of the signal output from the amplifier according to the characteristic of the loudspeaker determined by the determination unit.

### TECHNICAL FIELD

The present disclosure relates to a sound reproduction device.

### BACKGROUND ART

Because an electrically driven automobile and a hybrid automobile have a low noise, a pedestrian or the like hardly perceives approach of a vehicle at low speed traveling at which a road noise of the vehicle is small. For this reason, low-noise vehicles such as the electrically driven automobile and the hybrid automobile includes a sound reproduction device that generates a warning sound that is a continuous sound evoking a traveling state of the vehicle during traveling. The pedestrian or the like recognizes the approach of the vehicle by the warning sound.

For example, a conventional sound reproduction device includes a loudspeaker and a mechanism that adjusts sound volume (sound pressure) from the loudspeaker, and outputs the warning sound in which a variation in sound pressure is reduced by calibrating the sound pressure or the like output from the loudspeaker (for example, see PTL 1 and PTL 2).

### CITATION LIST

### Patent Literatures

PTL 1: Unexamined Japanese Patent Publication No. 2003-32777

PTL 2: Unexamined Japanese Patent Publication No. 2013-46140

### SUMMARY OF THE INVENTION

However, the variation in loudspeaker sound pressure of the warning sound output from the loudspeaker is larger than a variation of an electric circuit system such as an amplifier unit that drives the loudspeaker, and it is difficult to adjust the loudspeaker as a single unit before the loudspeaker is attached to the vehicle and to output the warning sound having the desired sound pressure after the loudspeaker is attached to the vehicle.

This is attributed to the following background due to a structure of the sound reproduction device in addition to the fact that the variation of the loudspeaker that is an electro-acoustic transducer is larger than the variation of the electric circuit system.

In order to surely cause the pedestrian or the like outside the vehicle to recognize the approach of the vehicle by the warning sound, it is necessary to output the minimum required sound volume. The required sound volume can be output when the amplifier unit is adjusted such that the minimum required sound volume is ensured according to the loudspeaker having a small sound pressure level in consideration of the loudspeaker having the large variation. However, when the adjustment state of the amplifier unit is applied to the loudspeaker having the large sound pressure level, the output sound volume of the warning sound is excessively large, and the excessively large sound volume gives discomfort to an occupant of the vehicle. In this case, the excessively large sound volume impairs a merit of the electrically driven automobile or the hybrid automobile having the low noise.

The sound pressure can be adjusted by collecting and analyzing the warning sound output from the loudspeaker using a microphone after the loudspeaker is attached to the vehicle. However, in a vehicle assembly factory, because disturbance such as noise is largely affected during the collection of the warning sound, it is difficult to stably and accurately adjust the warning sound output from the loudspeaker.

An object of the present disclosure is to provide a sound reproduction device that can accurately adjust the warning sound output from the loudspeaker at low cost.

According to one aspect of the present disclosure, a sound reproduction device includes a loudspeaker unit including a loudspeaker and an identifier that identifies a characteristic of the loudspeaker and an amplifier unit that amplifies a signal corresponding to a sound output from the loudspeaker. The amplifier unit includes an amplifier that amplifies the signal input from a sound source and outputs the amplified signal to the loudspeaker, a determination unit that determines the characteristic of the loudspeaker using the identifier, and an amplification degree adjuster that adjusts an amplification degree of the signal output from the amplifier. When the loudspeaker unit and the amplifier unit are connected to each other, the determination unit determines the characteristic of the loudspeaker of the connected loudspeaker unit from the identifier of the connected loudspeaker unit. The amplification degree adjuster adjusts the amplification degree of the signal output from the amplifier according to the characteristic of the loudspeaker determined by the determination unit.

Those comprehensive or specific aspects may be implemented by a system, a method, an integrated circuit, a computer program, or a computer-readable (non-transitory) recording medium such as a CD-ROM, or implemented by any combination of the system, the method, the integrated circuit, the computer program, and the recording medium.

The present disclosure can provide the sound reproduction device that can accurately adjust the warning sound output from the loudspeaker.

Therefore, the pedestrian or the like outside the vehicle can be sufficiently caused to recognize the approach of the vehicle by the warning sound having a proper sound volume, and the excessively large sound volume of the warning sound can be prevented from giving discomfort to the occupant of the vehicle.

### BRIEF DESCRIPTION OF DRAWINGS

FIG. 1 is a schematic diagram illustrating a configuration of a sound reproduction device according to an exemplary embodiment.

FIG. 2 is a schematic diagram illustrating a configuration of a loudspeaker unit of the exemplary embodiment.

FIG. 3 is a view illustrating an example of a loudspeaker characteristic and an identifier.

FIG. 4 is a flowchart illustrating a procedure of sound reproduction operation.

FIG. 5 is a view illustrating another configuration of the loudspeaker unit.

FIG. 6 is a view illustrating still another configuration of the loudspeaker unit.

FIG. 7 is a view illustrating yet another configuration of the loudspeaker unit.

### DESCRIPTION OF EMBODIMENT

### (Knowledge Underlying the Present Invention)

For example, the conventional sound reproduction device includes the loudspeaker and the mechanism that adjusts sound volume (sound pressure) from the loudspeaker, and outputs the warning sound in which the variation in sound pressure is reduced by adjusting (calibrating) the sound pressure or the like output from the loudspeaker.

For example, PTL 1 discloses a sound volume adjustment device connected to the loudspeaker through a signal line. The sound volume adjustment device outputs a calibration signal to the signal line, and detects an output signal of the loudspeaker, the output signal being generated by providing the calibration signal to the loudspeaker. Impedance of the loudspeaker is detected based on the output signal, and the sound volume output from the loudspeaker is adjusted based on the detected impedance.

PTL 2 discloses an electronic device having a function of recording and reproducing an audio signal. In the electronic device, sensitivities of right and left microphones are adjusted through a calibration process, and the audio signal can be recorded with a natural stereo sense.

However, each loudspeaker generally has the large variation in sound pressure, and in the technique described in PTL 1 and PTL 2, it is difficult to adjust the loudspeaker as a single unit before the loudspeaker is attached to the vehicle and to ensure the desired sound pressure after the loudspeaker is attached to the vehicle. The sound pressure can be calibrated by collecting and analyzing the sound output from the loudspeaker using the microphone after the loudspeaker is attached to the vehicle. However, in the vehicle assembly factory, because the disturbance such as the noise is largely affected during the collection of the sound, it is difficult to stably and accurately perform the calibration.

As to the warning sound output from the low-noise vehicle such as the electrically driven automobile and the hybrid automobile, National Highway Traffic Safety Administration (NHTSA) studies a regulation of a minimum sound pressure value. For example, the minimum sound pressure value is regulated for 8 frequency bands of 1/3 octave, and it is necessary to adjust the sound pressure of the loudspeaker such that the warning sound having at least the minimum sound pressure value is output when measurement is performed by a predetermined measurement method.

According to one aspect of the present disclosure, a sound reproduction device includes a loudspeaker unit including a loudspeaker and an identifier that identifies a characteristic of the loudspeaker and an amplifier unit that amplifies a signal corresponding to a sound output from the loudspeaker. The amplifier unit includes an amplifier that amplifies the signal input from a sound source and outputs the amplified signal to the loudspeaker, a determination unit that determines the characteristic of the loudspeaker using the identifier, and an amplification degree adjuster that adjusts an amplification degree of the signal output from the amplifier. When the loudspeaker unit and the amplifier unit are connected to each other, the determination unit determines the characteristic of the loudspeaker of the connected loudspeaker unit from the identifier of the connected loudspeaker unit. The amplification degree adjuster adjusts the amplification degree of the signal output from the amplifier according to the characteristic of the loudspeaker determined by the determination unit.

Consequently, when the loudspeaker unit includes the identifier having the identification information unique to the loudspeaker, the amplifier unit determines a variation in loudspeaker characteristic such as the unique sound pressure of each loudspeaker, and the adjustment can be performed such that the optimum loudspeaker characteristic is obtained. Thus, when the loudspeaker unit and the amplifier unit are connected to each other, the warning sound output from the loudspeaker can accurately be adjusted by determining the identifier of the loudspeaker. The desired sound pressure characteristic can be provided by a combination of any loudspeaker unit and the amplifier unit.

The identifier may be a resistor having a resistance value corresponding to the characteristic of the loudspeaker.

Consequently, the characteristics of the loudspeakers of a plurality of loudspeaker units can easily be determined using a predetermined resistance value.

The identifier may be a sound collection element that detects sound output from the loudspeaker.

Consequently, the warning sound can be adjusted in real time because the identifier and the sound pressure level are directly determined from the warning sound output from the loudspeaker.

The identifier may be a vibration detection element that detects vibration of the loudspeaker.

Consequently, the warning sound can be adjusted in real time because the identifier and the sound pressure level are directly determined by detecting the vibration of the loudspeaker corresponding to the warning sound.

The vibration detection element may be configured with a piezoelectric element.

Consequently, use of the piezoelectric element as the vibration detection element can efficiently convert the mechanical vibration that is the vibration of the loudspeaker into an electric signal, and easily perform the adjustment.

The vibration detection element may be configured with a photodetection element.

Consequently, the warning sound can be adjusted in real time because the identifier and the sound pressure level are directly determined from the vibration of the loudspeaker corresponding to the warning sound. The vibration of the loudspeaker is detected in a noncontact manner using light, so that the adjustment can accurately be performed.

Hereinafter, an exemplary embodiment of the present disclosure will be described with reference to the drawings. The following exemplary embodiment illustrates a specific example of the present invention. Numerical values, shapes, materials, components, arrangement positions and connection modes of the components, steps, and order of the steps illustrated in the following exemplary embodiment are only by way of example, and therefore are not intended to limit the present invention. Among constituent elements in the following exemplary embodiment, the constituent element that is not recited in the independent claim indicating the broadest concept is described as an optional constituent element.

### Exemplary Embodiment

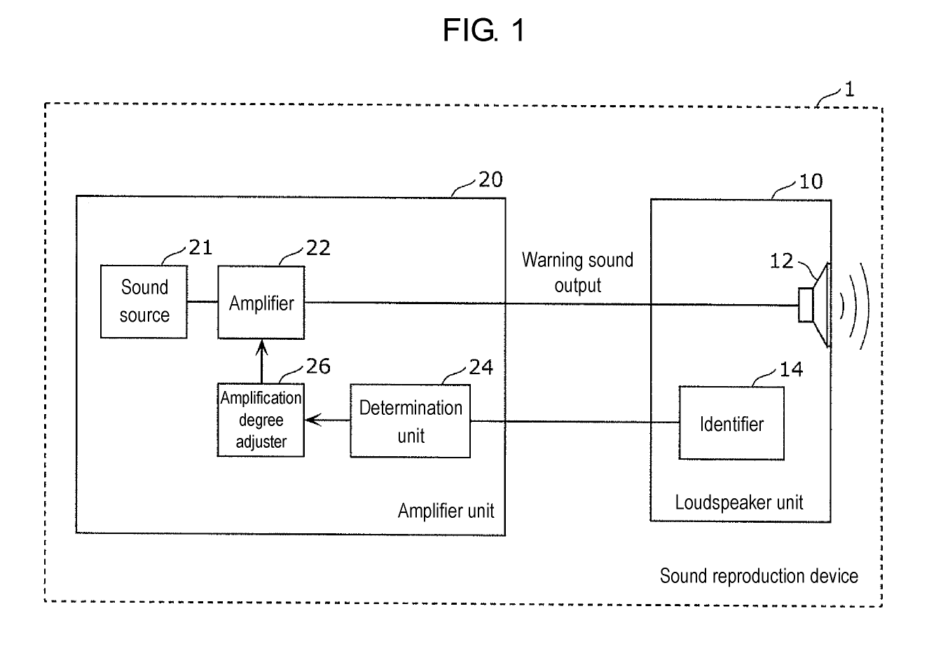

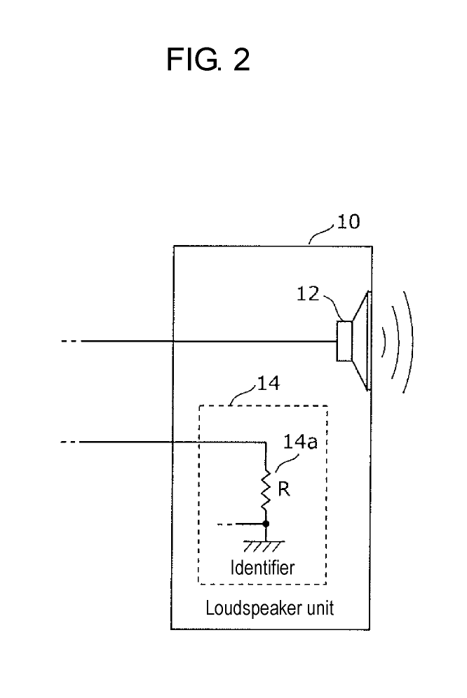

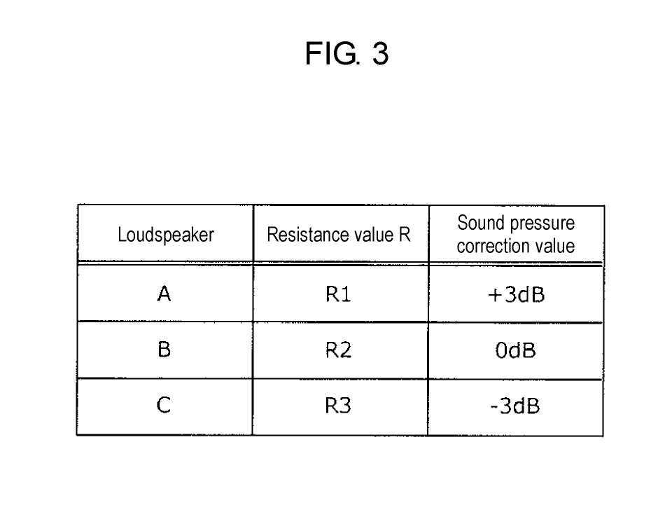

A configuration of a sound reproduction device of the exemplary embodiment will be described below. FIG. 1 is a schematic diagram illustrating the configuration of the sound reproduction device of the exemplary embodiment. FIG. 2 is a schematic diagram illustrating a configuration of a loudspeaker unit of the exemplary embodiment. FIG. 3 is a view illustrating an example of a loudspeaker characteristic and an identifier.

As illustrated in FIG. 1, sound reproduction device 1 includes loudspeaker unit 10 and amplifier unit 20.

Loudspeaker unit 10 includes loudspeaker 12 and identifier 14 indicating the loudspeaker characteristic. Loudspeaker unit 10 may include a loudspeaker box to which loudspeaker 12 is attached.

Loudspeaker 12 outputs warning sound informing an outside about approach of a vehicle. The warning sound is generated toward a pedestrian outside the vehicle, so that loudspeaker 12 is mounted outside the vehicle. Loudspeaker 12 has a function of converting an electric signal into a mechanical vibration, and outputs the warning sound of a sound pressure (sound volume) based on the electric signal. Loudspeaker 12 acts as not only a sound output element (loudspeaker) that converts the electric signal into the mechanical vibration, but also a sound collection element (microphone) that converts the mechanical vibration into the electric signal.

Identifier 14 is an element having identification information identifying a characteristic of loudspeaker 12. For example, identifier 14 includes resistor 14a as illustrated in FIG. 2. Resistor 14a has a resistance value corresponding to the characteristic of loudspeaker 12. When identifier 14 is configured with resistor 14a, the characteristics of the loudspeakers of a plurality of loudspeaker units can easily be determined using a predetermined resistance value.

The case where the characteristic of loudspeaker 12 is set to a sound pressure characteristic (a value of the sound pressure) will be described below.

The sound pressure of loudspeaker 12 is previously measured, and the resistance value of resistor 14a is decided according to the sound pressure. For example, as illustrated in FIG. 3, the resistance value of resistor 14a is decided according to the value of the sound pressure such that resistance value R1 is obtained when the sound pressure level is small (level A), resistance value R2 is obtained when the sound pressure level is middle (level B), and resistance value R3 is obtained when the sound pressure level is large (level C). The sound pressure level means a level when the sound pressure is divided into values having a predetermined range. The range of each sound pressure level may be decided in any way.

As illustrated in FIG. 1, amplifier unit 20 includes sound source 21, amplifier 22, determination unit 24, and amplification degree adjuster 26.

Sound source 21 generates the electric signal corresponding to the warning sound informing the outside about the approach of the vehicle. For example, the warning sound is engine sound. In this case, sound source 21 frequently uses a pseudo-engine sound or an electronic sound as the warning sound, and the warning sound includes a low-pitched sound of 300 Hz to 500 Hz and a component having frequencies of 1 kHz to 3 kHz. The warning sound may be a simple sine-wave signal sound. Sound source 21 need not to be included in amplifier unit 20, but sound source 21 may be provided outside amplifier unit 20 and externally connected to amplifier 22.

Amplifier 22 amplifies the signal (electric signal) corresponding to the sound output from sound source 21 with a predetermined amplification degree, and outputs the amplified signal to loudspeaker 12. At this point, the amplification degree is decided by amplification degree adjuster 26 (to be described in detail later). Amplifier 22 may be an analog amplifier or a digital amplifier.

Determination unit 24 determines identifier 14 of loudspeaker 12, and outputs a determination result to amplification degree adjuster 26. For example, determination unit 24 is configured with a microcomputer. The loudspeaker characteristic (in this case, the sound pressure level) of loudspeaker 12, the resistance value of resistor 14a, and a sound pressure correction value are previously stored in determination unit 24 while correlated with one another. For example, when loudspeaker 12 has the loudspeaker characteristic A as illustrated in FIG. 3, R1 is stored as the resistance value of resistor 14a, and +3 dB is stored as the sound pressure correction value.

Determination unit 24 measures the resistance value of resistor 14a constituting identifier 14. For example, determination unit 24 measures the resistance value of resistor 14a by measuring a voltage value and a current value at both ends of identifier 14. Determination unit 24 determines the characteristic of loudspeaker 12 based on the measured resistance value. Determination unit 24 decides the sound pressure correction value corresponding to the determined characteristic of loudspeaker 12. Determination unit 24 outputs the decided sound pressure correction value to amplification degree adjuster 26. Determination unit 24 may directly measure the resistance value of resistor 14a.

Amplification degree adjuster 26 adjusts an amplification degree of the electric signal amplified by amplifier 22. Specifically, amplification degree adjuster 26 adjusts amplifier 22 such that the electric signal corresponding to the warning sound is amplified by amplifier unit 20 using the sound pressure correction value output from determination unit 24. For example, amplification degree adjuster 26 is configured with a DSP (Digital Signal Processor).

Determination unit 24 and amplification degree adjuster 26 may be configured with an identical device such as a microcomputer.

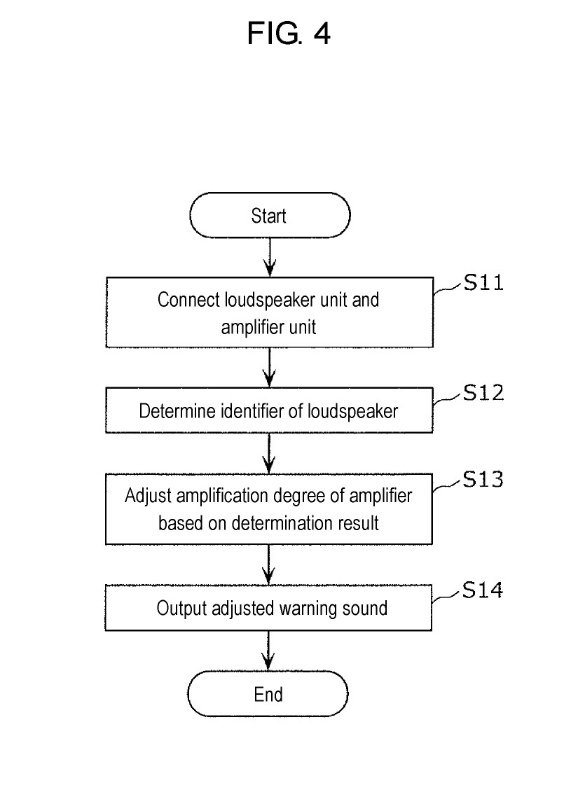

Sound reproduction operation in the sound reproduction device of the exemplary embodiment will be described below. FIG. 4 is a flowchart illustrating a procedure of the sound reproduction operation.

When loudspeaker unit 10 and amplifier unit 20 are connected to each other, determination unit 24 determines the characteristic of loudspeaker 12 of connected loudspeaker unit 10 from identifier 14 of connected loudspeaker unit 10, and amplification degree adjuster 26 adjusts the amplification degree of the sound pressure output from amplifier 22 according to the characteristic of loudspeaker 12 determined by determination unit 24.

As illustrated in FIG. 4, amplifier unit 20 is connected to loudspeaker unit 10 (step S11).

Then, determination unit 24 determines identifier 14 of loudspeaker 12 (step S12). As described above, determination unit 24 measures the resistance value of resistor 14a constituting identifier 14 by measuring the voltage value and the current value at both the ends of identifier 14. Determination unit 24 determines the characteristic of loudspeaker 12 based on the measured resistance value. Determination unit 24 outputs the sound pressure correction value corresponding to the determined characteristic of loudspeaker 12 to amplification degree adjuster 26.

Then, the amplification degree of amplifier 22 is adjusted based on the determination result of identifier 14 determined by determination unit 24 (step S13). Amplification degree adjuster 26 adjusts the amplification degree of amplifier 22.

Amplification degree adjuster 26 adjusts the amplification degree of amplifier 22 based on the determination result of determination unit 24. Specifically, amplification degree adjuster 26 adjusts amplifier 22 such that the electric signal corresponding to the warning sound is amplified by amplifier unit 20 using the sound pressure correction value output from determination unit 24.

Then, amplifier 22 outputs the adjusted electric signal to loudspeaker 12. Consequently, loudspeaker 12 outputs the warning sound having the adjusted sound pressure value (step S14).

Through the above procedure, the electric signal corresponding to the warning sound output from sound source 21 is adjusted based on identifier 14. The adjusted warning sound is output from loudspeaker 12.

The above-described loudspeaker characteristic is not limited to the sound pressure of the warning sound output from loudspeaker 12. For example, the loudspeaker characteristic may be a frequency band of the warning sound output from loudspeaker 12. In this case, the above-described correction value may be a frequency correction value, and the amplification degree adjuster may be a frequency adjuster that adjusts the frequency. In this case, a filter that passes the electric signal having a predetermined frequency band or a filter that cuts the electric signal having a predetermined frequency band may be used as the amplification degree adjuster. The loudspeaker characteristic may be both the sound pressure and the frequency band, or another characteristic.

Determination unit 24 and amplification degree adjuster 26 may be configured with an identical device such as a microcomputer.

Thus, sound reproduction device 1 of the exemplary embodiment includes loudspeaker unit 10 including loudspeaker 12 and identifier 14 that identifies the characteristic of loudspeaker 12 and amplifier unit 20 that amplifies the sound output from loudspeaker 12. Amplifier unit 20 includes amplifier 22 that amplifies the signal corresponding to the sound input from sound source 21 and outputs the amplified signal to loudspeaker 12, determination unit 24 that determines the loudspeaker characteristic using identifier 14, and amplification degree adjuster 26 that adjusts the amplification degree of the sound output from amplifier 22. When loudspeaker unit 10 and amplifier unit 20 are connected to each other, determination unit 24 determines the characteristic of loudspeaker 12 of connected loudspeaker unit 10 from identifier 14 of connected loudspeaker unit 10. Amplification degree adjuster 26 adjusts the amplification degree of the sound output from amplifier 22 according to the characteristic of loudspeaker 12 determined by determination unit 24.

Consequently, when loudspeaker unit 10 includes identifier 14 having the identification information unique to the loudspeaker, amplifier unit 20 determines a variation in loudspeaker characteristic such as the unique sound pressure of each loudspeaker 12, and the adjustment can be performed such that the optimum loudspeaker characteristic is obtained. Thus, when loudspeaker unit 10 and amplifier unit 20 are connected to each other, the warning sound output from loudspeaker 12 can accurately be adjusted by determining identifier 14 of loudspeaker unit 10. The desired sound pressure characteristic can be provided by a combination of any loudspeaker unit 10 and amplifier unit 20.

In the above-described exemplary embodiment, loudspeaker unit 10 of sound reproduction device 1 includes resistor 14a as identifier 14. However, the identifier is not limited to resistor 14a. First to third modifications of the exemplary embodiment will be described below.

### (First Modification)

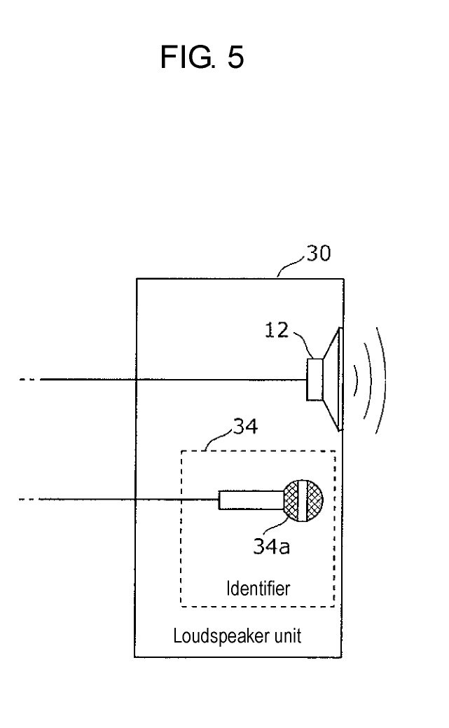

A first modification of the exemplary embodiment will be described below. FIG. 5 is a view illustrating a configuration of loudspeaker unit 30 of the first modification.

In the above-described exemplary embodiment, loudspeaker unit 10 of sound reproduction device 1 includes resistor 14a as identifier 14. However, for example, the identifier may be a sound collection element that detects the sound output from loudspeaker 12. For example, the sound collection element is a microphone. Consequently, amplifier 22 can adjust the warning sound in real time because determination unit 24 directly determines the identifier and the sound pressure level from the warning sound output from loudspeaker 12.

As illustrated in FIG. 5, loudspeaker unit 30 includes loudspeaker 12 and identifier 34. Identifier 34 is configured with sound collection element 34a. For example, sound collection element 34a is a microphone.

Sound collection element 34a collects the warning sound output from loudspeaker 12. The warning sound collected by sound collection element 34a is input to determination unit 24 of amplifier unit 20.

Determination unit 24 determines the sound pressure of the collected warning sound. For example, determination unit 24 classifies a level of the sound pressure of the collected warning sound in each predetermined range. Determination unit 24 determines the value of the collected sound pressure in each predetermined level such that level A is obtained when the sound pressure level is small, level B is obtained when the sound pressure level is middle, and level C is obtained when the sound pressure level is large.

Similarly to the above-described exemplary embodiment, amplification degree adjuster 26 adjusts the amplification degree of amplifier 22 based on the determination result of identifier 34 determined by determination unit 24. Then, amplifier 22 outputs the adjusted electric signal to loudspeaker 12. Consequently, loudspeaker 12 outputs the warning sound having the adjusted sound pressure value.

Through the above procedure, the electric signal corresponding to the warning sound output from sound source 21 is adjusted based on identifier 34. The adjusted warning sound is output from loudspeaker 12.

Sound collection element 34a is not limited to the microphone, but sound collection element 34a may be a loudspeaker. This is because not only the loudspeaker can output the sound by converting the electric signal into the mechanical vibration but also the loudspeaker can collect the sound by converting the mechanical vibration into the electric signal.

### (Second Modification)

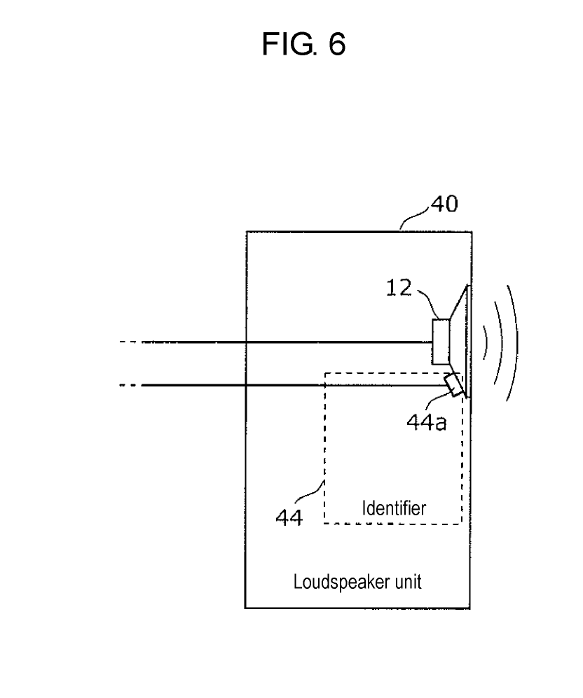

A second modification will be described below. FIG. 6 is a view illustrating a configuration of loudspeaker unit 40 of the second modification.

For example, the identifier in the loudspeaker unit may be a vibration detection element that detects the vibration of loudspeaker 12. A piezoelectric element may be used as the vibration detection element. Consequently, amplifier 22 can adjust the warning sound in real time because determination unit 24 directly determines the identifier and the sound pressure level by detecting the vibration of loudspeaker 12 corresponding to the warning sound. The use of the piezoelectric element can efficiently convert the mechanical vibration that is the vibration of loudspeaker 12 into the electric signal, and easily perform the adjustment.

A magnetostrictive element may be used instead of the piezoelectric element.

As illustrated in FIG. 6, loudspeaker unit 40 includes loudspeaker 12 and identifier 44. Identifier 44 is configured with piezoelectric element 44a that is the vibration detection element.

Piezoelectric element 44a is fixed to loudspeaker 12, and expands and contracts by receiving the vibration of loudspeaker 12 in outputting the warning sound from loudspeaker 12. A terminal through which voltage is output is provided in piezoelectric element 44a. The electric signal is output from piezoelectric element 44a through the terminal. That is, piezoelectric element 44a converts the mechanical vibration that is expansion and contraction into the electric signal according to a vibration amplitude of loudspeaker 12, and outputs the electric signal to determination unit 24.

Determination unit 24 determines the sound pressure of the warning sound output from piezoelectric element 44a. For example, determination unit 24 classifies the level of the vibration amplitude of loudspeaker 12, which is converted from the mechanical vibration into the electric signal and output to determination unit 24, in each predetermined range. Determination unit 24 determines the vibration amplitude of loudspeaker 12 in each predetermined level such that level A is obtained when loudspeaker 12 has the small vibration amplitude, level B is obtained when loudspeaker 12 has the middle vibration amplitude, level C is obtained when loudspeaker 12 has the large vibration amplitude.

Similarly to the above-described exemplary embodiment, amplification degree adjuster 26 adjusts the amplification degree of amplifier 22 based on the determination result of identifier 44 determined by determination unit 24. Then, amplifier 22 outputs the adjusted electric signal to loudspeaker 12. Consequently, loudspeaker 12 outputs the warning sound having the adjusted sound pressure value.

Through the above procedure, the electric signal corresponding to the warning sound output from sound source 21 is adjusted based on identifier 44.

The adjusted warning sound is output from loudspeaker 12.

The vibration detection element constituting identifier 44 need not to be piezoelectric element 44a. For example, as shown in the following third modification, the vibration detection element may be a photodetection element that detects the vibration using light. The third modification will be described below.

### (Third Modification)

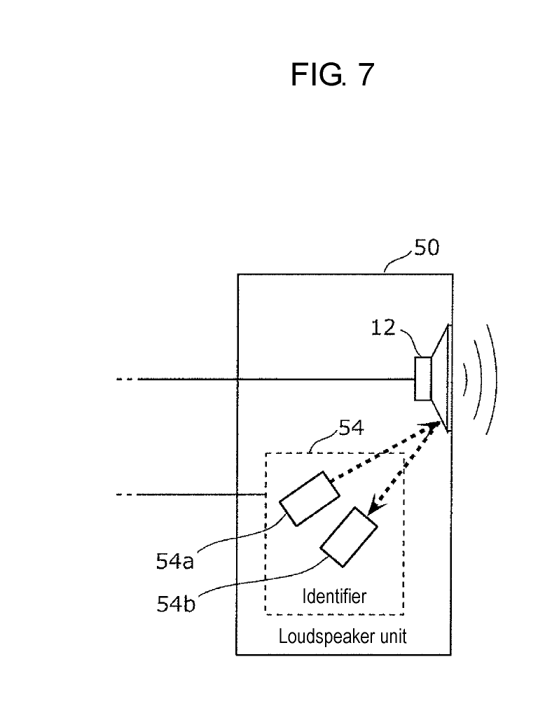

The third modification will be described below. FIG. 7 is a view illustrating a configuration of loudspeaker unit 50 of the third modification.

The identifier in the loudspeaker unit may be the vibration detection element that detects the vibration of loudspeaker 12. Specifically, the vibration detection element may be configured with photodetection element 54b. Consequently, amplifier 22 can adjust the warning sound in real time because determination unit 24 directly determines the identifier and the level from the vibration of loudspeaker 12 corresponding to the warning sound. The vibration of loudspeaker 12 is detected in a noncontact manner using the light, so that the adjustment can accurately be performed.

As illustrated in FIG. 7, loudspeaker unit 50 includes loudspeaker 12 and identifier 54. Identifier 54 includes optical output element 54a and photodetection element 54b that detects the light, which is output from optical output element 54a and reflected by loudspeaker 12. For example, a laser element that outputs a laser beam may be used as optical output element 54a. Light receiving elements such as a photosensor and a solid-state imaging element may be used as photodetection element 54b. Identifier 54 includes at least photodetection element 54b, and optical output element 54a may be attached to the outside of identifier 54.

Optical output element 54a emits the light toward loudspeaker 12. The light emitted from optical output element 54a is reflected by loudspeaker 12, and detected by photodetection element 54b. Photodetection element 54b detects the vibration of loudspeaker 12 in outputting the warning sound from loudspeaker 12 or the reflected light corresponding to the vibration of a diaphragm of loudspeaker 12. Photodetection element 54b detects an optical signal corresponding to the reflected light, converts the optical signal into the electric signal, and outputs the electric signal to determination unit 24.

Determination unit 24 determines the sound pressure of the warning sound output from photodetection element 54b. For example, determination unit 24 classifies the level of the vibration amplitude of loudspeaker 12, which is converted from the optical signal into the electric signal and output to determination unit 24, in each predetermined range. Determination unit 24 determines the vibration amplitude of loudspeaker 12 in each predetermined level such that level A is obtained when speaker 12 has the small vibration amplitude, level B is obtained when loudspeaker 12 has the middle vibration amplitude, level C is obtained when loudspeaker 12 has the large vibration amplitude.

Similarly to the above-described exemplary embodiment, amplification degree adjuster 26 adjusts the amplification degree of amplifier 22 based on the determination result of identifier 44 determined by determination unit 24. Then, amplifier 22 outputs the adjusted electric signal to loudspeaker 12. Consequently, loudspeaker 12 outputs the warning sound having the adjusted sound pressure value.

Through the above procedure, the electric signal corresponding to the warning sound output from sound source 21 is adjusted based on identifier 54. The adjusted warning sound is output from loudspeaker 12.

In the above configuration, the signal required for the identification of the identifier on the loudspeaker unit side is received as the information by connecting the identifier to amplifier unit 20. Alternatively, the information may be received in an indirect connection manner by wireless communication in addition to the direct connection. In this case, a part of a DC component output from amplifier 22 is used as power required for wireless communication, and the information is transmitted by wireless communication to perform the identification only during the initial connection.

The sound reproduction device of the exemplary embodiment and the modifications of the present invention has been described above. However, the present invention is not limited to the exemplary embodiment and the modifications.

At least a part of the processor included in the sound reproduction device of the above-described exemplary embodiment may be configured as a Large Scale Integration (LSI) that is an integrated circuit. Each functional block may individually be integrated into one chip, or some or all of the functional blocks may be integrated into one chip.

The integrated circuit is not limited to the LSI, but the integrated circuit may be configured with a dedicated circuit or a general-purpose processor. A Field Programmable Gate Array (FPGA) in which programming can be performed after LSI fabrication or a reconfigurable processor that can reconfigure connections and settings of circuit cells in the LSI may also be used in implementing the integrated circuit.

That is, in the above-described exemplary embodiment and modifications, the constituent elements may be implemented in dedicated hardware or with execution of software programs individually suitable for those constituent elements. A program execution unit such as a Central Processing Unit (CPU) and a processor reads and executes a software program stored in a recording medium such as a hard disk and a semiconductor memory, and thus each component may be implemented.

All the numerals described above are used only for the illustration of the present invention, but the present invention is not limited to the illustrated numerals.

The division of the functional block in the block diagram is only by way of example, and a plurality of functional blocks may be implemented as one functional block, one functional block may be divided into the plurality of functional blocks, or a part of the functions may be transferred to another functional block. The functions of the plurality of functional blocks having similar functions may be processed in parallel or in a time-sharing manner by single piece of hardware or software.

The procedure to perform the plurality of steps indicated by a flowchart or the like described above is used only for the specific illustration of the present invention, and the plurality of steps may be performed in a procedure other than the above procedure. A part of the steps may be performed at the same time as (in parallel to) another step.

The sound reproduction device according to one or more aspects has been described above based on the exemplary embodiment. However, the present invention is not limited to the exemplary embodiment. Configurations in which various modifications conceived by those skilled in the art are applied to the exemplary embodiment, and configurations established by combining structural elements in different exemplary embodiments may also fall within the scope of one or more aspects, without departing from the scope of the present invention.

### INDUSTRIAL APPLICABILITY

The present invention is suitable for the sound reproduction device mounted on low-noise vehicles such as the electrically driven automobile and the hybrid automobile.

### REFERENCE MARKS IN THE DRAWINGS

1: sound reproduction device

10, 30, 40, 50: loudspeaker unit

12: loudspeaker

14, 34, 44, 54: identifier

20: amplifier unit

21: sound source

22: amplifier

24: determination unit

26: amplification degree adjuster

34a: sound collection element

44a: piezoelectric element (vibration detection element)

54a: optical output element

54b: photodetection element (vibration detection element)

1. A sound reproduction device comprising:
a loudspeaker unit including a loudspeaker and an identifier that identifies a characteristic of the loudspeaker; and
an amplifier unit that amplifies a signal corresponding to a sound to be output from the loudspeaker,
wherein the amplifier unit includes:
an amplifier that amplifies the signal input from a sound source and outputs the amplified signal to the loudspeaker;
a determination unit that determines the characteristic of the loudspeaker using the identifier; and
an amplification degree adjuster that adjusts an amplification degree of the signal output from the amplifier, and
when the loudspeaker unit and the amplifier unit are connected to each other,
the determination unit determines the characteristic of the loudspeaker of the connected loudspeaker unit from the identifier of the connected loudspeaker unit, and
the amplification degree adjuster adjusts the amplification degree of the signal to be output from the amplifier according to the characteristic of the loudspeaker determined by the determination unit.

2. The sound reproduction device according to claim 1, wherein the identifier is a resistor having a resistance value corresponding to the characteristic of the loudspeaker.

3. The sound reproduction device according to claim 1, wherein the identifier is a sound collection element that detects sound output from the loudspeaker.

4. The sound reproduction device according to claim 1, wherein the identifier is a vibration detection element that detects vibration of the loudspeaker.

5. The sound reproduction device according to claim 4, wherein the vibration detection element is configured with a piezoelectric element.

6. The sound reproduction device according to claim 4, wherein the vibration detection element is configured with a photodetection element.
